(19) United States
(12) Patent Application Publication
(10) Pub. No.: US 2015/0171255 A1
(43) Pub. Date: Jun. 18, 2015

(54) SOLAR CELL AND METHOD OF FORMING THE SAME AND METHOD FOR FORMING N-TYPE ZNS LAYER

(71) Applicant: INDUSTRIAL TECHNOLOGY RESEARCH INSTITUTE, Hsinchu (TW)

(72) Inventors: Wei-Tse HSU, Taoyuan City (TW); Shih-Cheng CHANG, Taipei City (TW)

(73) Assignee: INDUSTRIAL TECHNOLOGY RESEARCH INSTITUTE, Hsinchu (TW)

(21) Appl. No.: 14/141,094

(22) Filed: Dec. 26, 2013

(30) Foreign Application Priority Data
Dec. 12, 2013 (TW) 102145804

(51) Int. Cl. H01L 31/0749; H01L 31/18; H01L 31/0224; H01L 31/0296; H01L 31/042

(52) U.S. Cl. CPC H01L 31/0749; H01L 31/0296; H01L 31/042; H01L 31/022466; H01L 31/1828; H01L 31/1884

(57) ABSTRACT

Disclosed is a solar cell including a substrate, an electrode layer disposed on the substrate, a p-type light-absorption layer disposed on the electrode layer, an n-type ZnS layer disposed on the p-type light-absorption layer, and a transparent electrode layer disposed on the n-type ZnS layer. The substrate can be immersed into an acidic solution of zinc salt, chelate, and thioacetamide, thereby forming the n-type ZnS layer on the substrate.

### CROSS REFERENCE TO RELATED APPLICATIONS

The present application is based on, and claims priority from, Taiwan Application Serial Number 102145804, filed on Dec. 12, 2013, the disclosure of which is hereby incorporated by reference herein in its entirety

### TECHNICAL FIELD

The technical field relates to a solar cell, and in particular relates to its buffer layer and a method of forming the same.

### BACKGROUND

Global industries have greatly developed in recent years. Traditional power supplies have the advantage of low cost, but they also have potential problems such as causing radiation and environmental pollution. Many research departments are focusing on green alternative energy, and the solar cells are very promising. Traditional solar cells were mainly based on silicon wafers, but thin-film solar cells were developed in recent years. However, the copper indium gallium selenide (GIGS) series solar cells are the best choice for non-toxicity, high efficiency, and high stability.

CIGS is a chalcopyrite compound with a tetragonal crystal structure. CIGS can be applied in solar cells due to a high optical absorption coefficient, wide light-absorption band, stable chemical properties, and direct bandgap. A general CIGS solar cell includes an electrode layer, a CIGS layer, a CdS layer, an i-ZnO layer, an AZO layer, and an optional finger electrode layer sequentially formed on a substrate. The i-ZnO layer may retard the problem of incomplete coverage of the buffer layer, and efficiently inhibit leakage current of the solar cell. In addition, the problem of the CdS layer being damaged by ion bombardment during sputtering of the AZO layer can be reduced by the i-ZnO layer. However, the i-ZnO layer absorbs the incident light. Moreover, the current collection is obstructed by the i-ZnO layer with high resistance. Moreover, the i-ZnO layer formed by sputtering takes more processing time.

Accordingly, a novel CIGS cell free of the i-ZnO layer is called for.

### SUMMARY

One embodiment of the disclosure provides a solar cell, comprising: a substrate; an electrode layer disposed on the substrate; a p-type light-absorption layer disposed on the electrode layer; an n-type ZnS layer disposed on the p-type light-absorption layer; and a transparent electrode layer disposed on the n-type ZnS layer.

One embodiment of the disclosure provides a method of forming an n-type ZnS layer, comprising: immersing a substrate into an acidic solution of zinc salt, chelating agent, and thioacetamide to form an n-type ZnS layer on the substrate.

One embodiment of the disclosure provides a method of forming a solar cell, comprising: providing a substrate; forming an electrode layer on the substrate; forming a p-type light-absorption layer on the electrode layer; forming a n-type ZnS layer on the p-type absorption layer, comprising: immersing the substrate into an acidic solution of zinc salt, chelating agent, and thioacetamide; and forming a transparent electrode layer on the n-type ZnS layer.

A detailed description is given in the following embodiments with reference to the accompanying drawings.

### BRIEF DESCRIPTION OF THE DRAWINGS

The disclosure can be more My understood by reading the subsequent detailed description and examples with references made to the accompanying drawings, wherein:

FIG. 1 shows a solar cell in one embodiment of the disclosure;

FIG. 2 shows a solar cell in one embodiment of the disclosure; and

FIG. 3 shows a solar cell in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

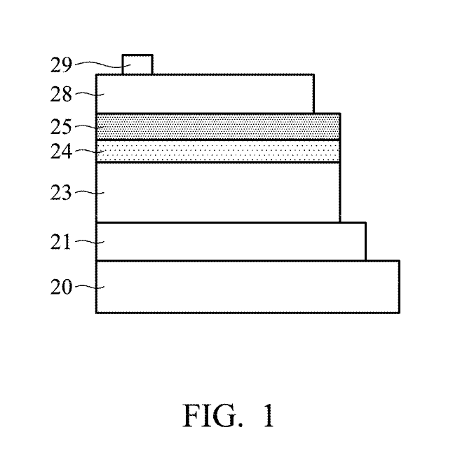

FIG. 1 shows a solar cell 20 in one embodiment of the disclosure. First, a substrate 20 such as plastic, stainless steel, glass, quartz, or other general substrate material is provided. An electrode layer 21 is then formed on the substrate 20 by sputtering, physical vapor deposition, spray coating, or the likes. In one embodiment, the electrode layer 21 can be molybdenum, copper, silver, gold, platinum, other metals, or alloys thereof. A p-type light-absorption layer 23 is then formed on the electrode layer 21. In one embodiment, the p-type light-absorption layer 23 can be copper indium gallium selenide (CMS), copper indium gallium selenide sulfide (CIGSS), copper gallium selenide (CGS), copper gallium selenide sulfide (CGSS), or copper indium selenide (CIS). The p-type light-absorption layer 23 can be formed by evaporation, sputtering, plating, nanoparticle coating, and the likes. See Solar energy, 77 (2004) page 749-756 and Thin solid films, 480-481 (2005) page 99-109.

An n-type ZnS layer 24 is then formed on the p-type light-absorption layer 23 to form a p-n junction. In one embodiment, the n-type ZnS layer 24 can be formed by wet chemical bath deposition (CBD). For example, the substrate 20 can be immersed into an acidic solution of zinc salt, chelating agent, and thioacetamide to form the n-type ZnS layer on the substrate 20. In one embodiment, the zinc salt can be zinc acetate, zinc sulfate, zinc chloride, zinc nitrate, or the likes, and the acidic solution has a zinc salt concentration of 0.001M to 1M. An overly low zinc salt concentration may cause an overly slow film growth or even no film growth, thereby influencing the device's properties. An overly high zinc salt concentration may cause an overly fast (uncontrollable) film growth and an overly thick film, thereby largely increasing the series resistance of the solar cell and degrading the device efficiency. In one embodiment, the chelating agent can be tartaric acid, succinic acid, sodium citrate, or combinations thereof, and the acidic solution has a chelating agent concentration of 0.001M to 1M. An overly low chelating agent concentration may cause an overly fast homogeneous nucleation, such that a large amount of nanoparticles are formed in the acidic solution and then precipitated on the light-absorption layer. The film structure of the precipitation is loose with a low quality. An overly high chelating agent concentration will chelate all zinc ions, such that the film growth is largely slowed. In one embodiment, the acidic solution has a thioacetamide concentration of 0.001M to 1M. An overly low thioacetamide concentration will influence the pH value of the acidic solution. The acidic solution with an overly high pH value may have an overly high OH⁻ concentration, such that the light transmittance of the ZnS film is decreased due to hydroxide compound in the ZnS film. An overly high thioacetamide concentration causes overly fast film growth, such that the film is loose with a low quality. The acidic solution has a pH value of 1.5 to 5. An overly high pH value of the acidic solution may accelerate film growth, but the film will include the hydroxide compound. Hydroxide compound not only reduces the bandgap of the film, but also reduces short-wavelength light transmittance. An overly low pH value of the acidic solution not only damages the light-absorption surface, but also degrades the film quality due to overly fast homogeneous nucleation. The substrate is immersed into the acidic solution at a temperature of about 50° C. to 100° C., and the temperature obviously influences the film's properties. An overly high temperature causes a violent reaction, e.g. a homogeneous nucleation, to directly influence the film coverage. An overly low temperature may largely slow the film growth. In one embodiment, the electrode layer 21 and the p-type light-absorption layer 23 are formed on the substrate before immersing the substrate 20 into the acidic solution, such that the n-type ZnS layer 24 is formed on the p-type light-absorption layer 23. The n-type ZnS layer 24 has a thickness of 5 nm to 100 nm. In another embodiment, the n-type ZnS layer 24 has a thickness of 10 nm to 40 nm. An overly thin n-type ZnS layer 24 will cause a poor p-n junction due to incomplete coverage, thereby largely degrading the solar cell efficiency. An overly thick n-type ZnS layer 24 may crack, causing leakage current, increasing the series resistance of the solar cell, and decreasing the solar cell efficiency.

A CdS layer 25 is then formed on the n-type ZnS layer 24. In one embodiment, the formation CdS layer 25 may be referred to Solar energy, 77 (2004) page 749-756. The substrate with the above structure can be immersed into a solution of cadmium sulfate, thiourea, and ammonia at a temperature of 50° C. to 75° C. In one embodiment. the CdS layer has a thickness of 5 nm to 100 nm. An overly thin CdS layer 25 will cause leakage current due to poor coverage, thereby negatively influencing the solar cell efficiency. An overly thick CdS layer 25 not only decreases the light transmittance, but also largely increases the series resistance of the solar cell to decrease the solar cell efficiency.

A transparent electrode layer 28 is then formed on the CdS layer 25. In one embodiment, the transparent electrode layer 28 can be aluminum zinc oxide (AZO), indium tin oxide (ITO), antimony tin oxide (ATO), or other transparent conductive material. The transparent electrode 28 can be formed by sputtering, evaporation, atomic layered deposition, pyrolysis, nanoparticle coating, or other related film coating processes.

In one embodiment, a finger electrode 29 can be optionally formed on the transparent electrode layer 28. The finger electrode can be nickel aluminum alloy (Ni/Al), and can be formed by sputtering, lithography, etching, and/or other suitable processes. In one embodiment, the finger electrode 29 can be omitted when the transparent electrode layer 28 has a small surface area.

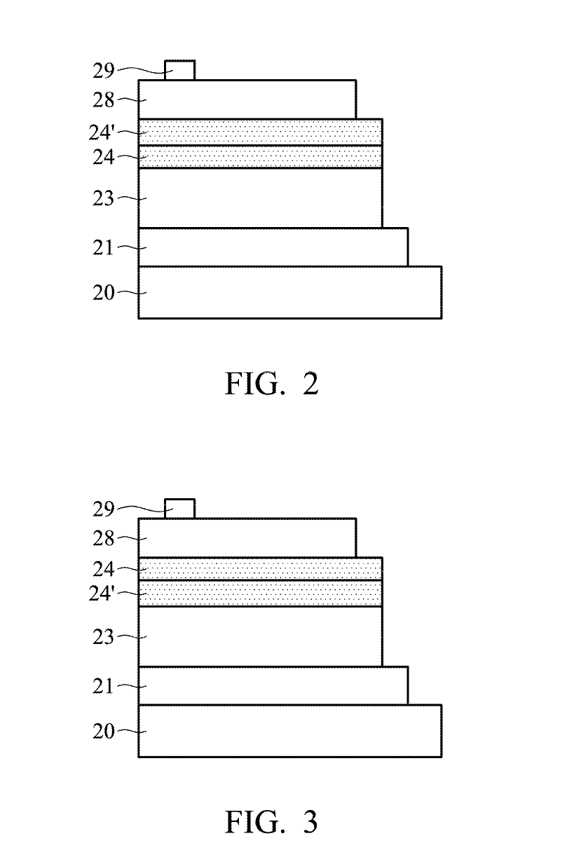

In one embodiment, another n-type ZnS layer 24′ can be deposited in an alkaline solution before or after the step of depositing the n-type ZnS layer 24 in the acidic solution, as shown in FIGS. 2 and 3. The n-type ZnS layer 24′ can be disposed between the substrate and the n-type ZnS layer 24, or on the n-type ZnS layer 24. The location of the n-type ZnS layer 24′ is determined by the process order. For example, the substrate 20 is immersed into an alkaline solution of zinc salt, thiourea, and ammonia, thereby forming the n-type ZnS layer 24′. In one embodiment, the zinc salt can be zinc acetate, zinc sulfate, zinc chloride, zinc nitrate, or the likes, and the alkaline solution has a zinc salt concentration of 0.001M to 1M. An overly low zinc salt concentration may cause an overly slow film growth or even no film growth, thereby influencing the device property. An overly high zinc salt concentration may cause an overly fast (uncontrollable) film growth and an overly thick film, thereby largely increasing the series resistance of the solar cell and degrading the device efficiency. In one embodiment, the alkaline solution has a thiourea concentration of 0.005M to 2M. An overly low thiourea concentration may cause an overly slow film growth. In addition, the major chemical composition of the film will be hydroxide compound due to insufficient sulfur source. An overly high thiourea concentration may cause an overly large amount of homogeneous nucleation, which may scatter the incident light and reduce the amount of light entering the light-absorption layer. In addition, the film composed of the homogeneous nucleation is usually loose and low-quality. In one embodiment, the alkaline solution has an ammonia concentration of 0.5M to 5M. An overly low ammonia concentration may cause an overly fast homogeneous nucleation, such that a large amount of nanoparticles are formed in the alkaline solution and then precipitated. The film structure of the precipitation is loose with a low quality. The alkaline solution has a pH value of 9 to 12.5. An overly high pH value may cause the film to have a major composition of hydroxide compound. The hydroxide compound is not only unstable, but it also has a low band gap. As such, the amount of light entering the light-absorption layer is reduced, thereby decreasing the short-circuit current of the solar cell. Moreover, an overly low bandgap will cause a bandgap mismatch of the junction between the n-type ZnS layer 24′ and the underlying/overlying layers, thereby decreasing the solar cell efficiency. An overly low pH value may result in the film containing too much sulfur, such that a bandgap mismatch of the junction between the n-type ZnS layer 24′ and the underlying/overlying layers will decrease the solar cell efficiency. In one embodiment, the substrate is immersed into the alkaline solution at a temperature of 50° C. to 100° C. The n-type ZnS layer 24′ deposited in the alkaline solution may have a thickness of 5 nm to 100 nm. In another embodiment, the n-type ZnS layer 24′ has a thickness of 10 nm to 40 nm. An overly thin n-type ZnS layer 24′ will cause leakage current due to incomplete coverage, thereby negatively influencing the solar cell efficiency. An overly thick n-type ZnS layer 24′ may reduce the light transmittance, and increase the series resistance of the solar cell to decrease the solar cell efficiency. Note that the CdS layer 25 in FIG. 1 can be omitted when the n-type ZnS layer 24 is formed by the acidic solution and the n-type ZnS layer 24′ is formed by the alkaline solution. In other words, the transparent electrode layer 29 can be directly formed on the n-type ZnS layer 24 or the n-type ZnS layer 24′ of the hi-layered structure, as shown in FIG. 2 or 3.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Comparative Example 1

A stainless steel plate with a thickness of 100 μm was used as a substrate, and a chromium layer (for an impurity barrier) with a thickness of 1000 nm was sputtered on the substrate. A molybdenum electrode layer with a thickness of 1000 nm was then sputtered on the chromium layer. Metal precursors were coated on the molybdenum electrode by a nanoparticle coating method, and then selenized to form a CIGS light-absorption layer with a thickness of 2500 nm.

Subsequently, a CdS layer with a thickness of 50 nm was formed on the CIGS light-absorption layer by the following steps. A solution of cadmium sulfate (0.0015M), a thiourea (0.0075M), and ammonia (1.5M) was prepared. The substrate was immersed in the solution at 65° C. for 12 minutes to form the CdS layer. An i-ZnO layer with a thickness of 50 nm was sputtered on the CdS layer, an AZO layer with a thickness of 350 nm was then sputtered on the i-ZnO layer, and a Ni/Al finger electrode layer was formed on the AZO layer to complete a solar cell. A bi-layered structure of the CdS layer and the i-ZnO layer had a light transmittance of about 76.6% for a light with a wavelength of 300 nm to 1100 nm. The performance of the solar cell is shown in Table 1.

### Example 1

A stainless steel plate with a thickness of 100 μm was used as a substrate, and a chromium layer (for an impurity barrier) with a thickness of 1000 nm was sputtered on the substrate. A molybdenum electrode layer with a thickness of 1000 nm was then sputtered on the chromium layer. Metal precursors were coated on the molybdenum electrode by a nanoparticle coating method, and then selenized to form a CIGS light-absorption layer with a thickness of 2500 nm.

Subsequently, zinc sulfate, tartaric acid, and thioacetamide were dissolved in 500 mL of de-ionized water to form an acidic solution with a pH value of about 2.5. The acidic solution has a zinc sulfate concentration of 0.0051M, a tartaric acid concentration of 0.03M, and a thioacetamide concentration of 0.01M. The substrate with the CIGS light-absorption layer coated thereon was immersed into the acidic solution at about 75° C. to 85° C. for 10 minutes, thereby forming an n-type ZnS layer with a thickness of 35 nm on the CIGS light-absorption layer.

Subsequently, a CdS layer with a thickness of 35 nm was formed on the n-type ZnS layer by the following steps. A solution of cadmium sulfate (0.0015M), a thiourea (0.0075M), and ammonia (1.5M) was prepared. The substrate was immersed in the solution at 65° C. for 10 minutes to form the CdS layer. An AZO layer with a thickness of 350 nm was then sputtered on the CdS layer, and a Ni/Al finger electrode layer was formed on the AZO layer to complete a solar cell. A hi-layered structure of the n-type ZnS layer and the CdS layer had a light transmittance of about 80.6% for a light with a wavelength of 300 nm to 1100 nm. The performance of the solar cell is shown in Table 1.

### Example 2

A stainless steel plate with a thickness of 100 μm was used as a substrate, and a chromium layer (for an impurity barrier) with a thickness of 1000 nm was sputtered on the substrate. A molybdenum electrode layer with a thickness of 1000 nm was then sputtered on the chromium layer. Metal precursors were coated on the molybdenum electrode by a nanoparticle coating method, and then selenized to form a CIGS light-absorption layer with a thickness of 2500 nm.

Subsequently, zinc sulfate, tartaric acid, and thioacetamide were dissolved in 500 mL of de-ionized water to form an acidic solution with a pH value of about 2.5. The acidic solution has a zinc sulfate concentration of 0.005M, a tartaric acid concentration of 0.03M, and a thioacetamide concentration of 0.01M. The substrate with the CIGS light-absorption layer coated thereon was immersed into the acidic solution at about 75° C. to 85° C. for 7 minutes, thereby forming an n-type ZnS layer with a thickness of 2.0 nm on the CIGS light-absorption layer.

Subsequently, a CdS layer with a thickness of 15 nm was formed on the n-type ZnS layer by the following steps. A solution of cadmium sulfate (0.0015M), a thiourea (0.0075M), and ammonia (1.5M) was prepared. The substrate was immersed in the solution at 65° C. for 5 minutes to form the CdS layer. An AZO layer with a thickness of 350 nm was then sputtered on the CdS layer, and a Ni/Al finger electrode layer was formed on the AZO layer to complete a solar cell. A bi-layered structure of the n-type ZnS layer and the CdS layer had a light transmittance of about 84.2% for a light with a wavelength of 300 nm to 1100 nm. The performance of the solar cell is shown in Table 1.

TABLE 1

| | V_{OC} | J_{SC} | | Conversion | Rₛₕ | Rs |
|---|---|---|---|---|---|---|
| | (V) | (mA/cm²) | FF (%) | efficiency (%) | (Ω) | (Ω) |
| Comparative | 0.567 | 18.35 | 70.75 | 7.36 | 1774 | 7.6 |
| Example 1 | | | | | | |
| Example 1 | 0.566 | 19.08 | 68.44 | 7.40 | 2302 | 8.3 |
| Example 2 | 0.568 | 19.92 | 70.15 | 7.95 | 2247 | 7.9 |

As shown in Table 1, the conversion efficiency of the solar cell in Example 1 was similar to that of Comparative Example 1 due to their open-circuit voltage (Voc) being similar. Although the fill factor (FF) of Comparative Example 1 was higher than those of Examples 1 and 2, the short-circuit current (Jsc) of Example 1 is higher than that of Comparative Example 1. As such, the conversion efficiency of the solar cell in Example 1 was similar to that of Comparative Example 1. The zinc sulfate has a higher resistivity than the cadmium sulfate, thereby resulting in the solar cell in Example 1 having a lower fill factor than the solar cell in Comparative Example 1. The phenomenon of the sulfate influence can be proven in Example 2. The open-circuit voltage of the solar cell in Example 2 was similar to that of Comparative Example 1, but the amount of the incident light entering the CIGS light-absorption layer can be increased by thinning the thickness of the n-type ZnS layer and the CdS layer. As a result, the short-circuit current of the solar cell in Example 2 was obviously higher than that of Comparative Example 1. Comparing Examples 1 and 2, the series resistance (Rs) of the solar cell can be reduced by thinning the thickness of the n-type ZnS layer and the CdS layer, thereby enhancing the fill factor of the solar cell. Therefore, the conversion efficiency of the solar cell in Example 2 was higher than that of Example 1.

### Example 3

A stainless steel plate with a thickness of 100 μm was used as a substrate, and a chromium layer (for an impurity barrier) with a thickness of 1000 nm was sputtered on the substrate. A molybdenum electrode layer with a thickness of 1000 nm was then sputtered on the chromium layer. Metal precursors were coated on the molybdenum electrode by a nanoparticle coating method, and then selenized to form a CIGS light-absorption layer with a thickness of 2500 nm.

Subsequently, zinc sulfate, tartaric acid, and thioacetamide were dissolved in 500 mL of de-ionized water to form an acidic solution with a pH value of about 2.5. The acidic solution has a zinc sulfate concentration of 0.005M, a tartaric acid concentration of 0.03M, and a thioacetamide concentration of 0.01M. The substrate with the CIGS light-absorption layer coated thereon was immersed into the acidic solution at about 75° C. to 85° C. for 10 minutes, thereby forming an n-type ZnS layer with a thickness of 35 nm on the CIGS light-absorption layer.

Subsequently, another n-type ZnS layer with a thickness of 20 nm was formed on the ZnS layer by the following steps. Zinc sulfate, thiourea, and ammonium were mixed to form an alkaline solution with a pH value of about 12. The alkaline solution has a zinc sulfate concentration of 0.01M, a thiourea concentration of 0.08M, and an ammonia concentration of 2.5M. The substrate with the n-type ZnS layer coated thereon was immersed into the alkaline solution at about 80° C. for 20 minutes, thereby forming another n-type ZnS layer on the n-type ZnS layer. Subsequently, an AZO layer with a thickness of 350 nm was sputtered on the n-ZnS layer, and a Ni/Al finger electrode layer was formed on the AZO layer to complete a solar cell. The performance of the solar cell is shown in Table 2.

### Example 4

A stainless steel plate with a thickness of 100 μm was used as a substrate, and a chromium layer (for an impurity barrier) with a thickness of 1000 nm was sputtered on the substrate. A molybdenum electrode layer with a thickness of 1000 nm was then sputtered on the chromium layer. Metal precursors were coated on the molybdenum electrode by a nanoparticle coating method, and then selenized to form a CIGS light-absorption layer with a thickness of 2500 nm.

Subsequently, an n-type ZnS layer with a thickness of 20 nm was formed on the CIGS light-absorption layer by the following steps. Zinc sulfate, thiourea, and ammonium were mixed to form an alkaline solution with a pH value of about 12. The alkaline solution has a zinc sulfate concentration of 0.01M, a thiourea concentration of 0.08M, and an ammonia concentration of 2.5M. The substrate with the n-type ZnS layer coated thereon was immersed into the alkaline solution at about 80° C. for 20 minutes, thereby forming the n-type ZnS layer on the CIGS light-absorption layer.

Subsequently, zinc sulfate, tartaric acid, and thioacetamide were dissolved in 500 mL of de-ionized water to form an acidic solution with a pH value of about 2.5. The acidic solution has a zinc sulfate concentration of 0.005M, a tartaric acid concentration of 0.03M, and a thioacetamide concentration of 0.01M. The substrate with the n-type ZnS layer formed thereon was immersed into the acidic solution at about 75° C. to 85° C. for 10 minutes, thereby forming another n-type ZnS layer with a thickness of 35 nm on the n-type ZnS layer. Subsequently, an AZO layer with a thickness of 350 nm was sputtered on the n-ZnS layer, and a Ni/Al finger electrode layer was formed on the AZO layer to complete a solar cell. The performance of the solar cell is shown in Table 2.

TABLE 2

| | V_{OC} | J_{SC} | | Conversion | Rₛₕ | Rs |
|---|---|---|---|---|---|---|
| | (V) | (mA/cm²) | FF (%) | efficiency (%) | (Ω) | (Ω) |
| Example 3 | 0.560 | 25.65 | 51.25 | 7.36 | 187 | 8.2 |
| Example 4 | 0.538 | 28.54 | 49.93 | 7.66 | 408 | 14.1 |

It will be apparent to those skilled in the art that various modifications and variations can be made to the disclosed methods and materials. It is intended that the specification and examples be considered as exemplary only, with a true scope of the disclosure being indicated by the following claims and their equivalents.

What is claimed is:

1. A solar cell, comprising:
a substrate;
an electrode layer disposed on the substrate;
a p-type light-absorption layer disposed on the electrode layer;
an n-type ZnS layer disposed on the p-type light-absorption layer; and
a transparent electrode layer disposed on the n-type ZnS layer.

2. The solar cell as claimed in claim 1, further comprising a finger electrode disposed on the transparent electrode layer.

3. The solar cell as claimed in claim 1, wherein the electrode layer comprises molybdenum, copper, silver, gold, or platinum.

4. The solar cell as claimed in claim 1, wherein the p-type light-absorption layer comprises copper indium gallium selenide, copper indium gallium selenide sulfide, copper gallium selenide, copper gallium selenide sulfide, or copper indium selenide.

5. The solar cell as claimed in claim 1, wherein the transparent electrode layer comprises aluminum zinc oxide, indium tin oxide, or antimony tin oxide.

6. The solar cell as claimed in claim 1, wherein the n-type ZnS layer has a thickness of 5 nm to 1.00 nm.

7. The solar cell as claimed in claim 1, further comprising a CdS layer between the n-type ZnS layer and the transparent electrode layer.

8. The solar cell as claimed in claim 7, wherein the CdS layer has a thickness of 5 nm to 100 nm.

9. The solar cell as claimed in claim 1, wherein the n-ZnS layer is a bi-layered structure, one layer of the bi-layered structure is formed by immersing the substrate into an acidic solution of zinc salt, chelating agent, and thioacetamide, and another layer of the bi-layered structure is formed by immersing the substrate into an alkaline solution of zinc salt, thiourea, and ammonia.

10. A method of forming an n-type ZnS layer, comprising:
immersing a substrate into an acidic solution of zinc salt, chelating agent, and thioacetamide to form an n-type ZnS layer on the substrate.

11. The method as claimed in claim 10, wherein the zinc salt comprises zinc sulfate, zinc acetate, zinc chloride, or zinc nitrate, and the acidic solution has a zinc salt concentration of 0.001M to 1M.

12. The method as claimed in claim 10, wherein the chelating agent comprises tartaric acid, succinic acid, or combinations thereof, and the acidic solution has a chelating agent concentration of 0.001M to 1M.

13. The method as claimed in claim 10, wherein the acidic solution has a thioacetamide concentration of 0.001M to 1M.

14. The method as claimed in claim 10, wherein the n-type ZnS layer has a thickness of 5 nm to 100 nm.

15. The method as claimed in claim 10, further comprising a step of immersing the substrate in an alkaline solution of zinc salt, thiourea, and ammonia to form another n-type ZnS layer on the substrate before or after forming the ZnS layer.

16. A method of forming a solar cell, comprising:
providing a substrate;
forming an electrode layer on the substrate;
forming a p-type light-absorption layer on the electrode layer;
forming a n-type ZnS layer on the p-type absorption layer, comprising:
immersing the substrate into an acidic solution of zinc salt, chelating agent, and thioacetamide; and
forming a transparent electrode layer on the n-type ZnS layer.

17. The method as claimed in claim 16, further comprising a step of forming a finger electrode on the transparent electrode layer.

18. The method as claimed in claim 16, further comprising a step of forming a CdS layer between the n-type ZnS layer and the transparent electrode layer.

19. The method as claimed in claim 16, further comprising a step of immersing the substrate in an alkaline solution of zinc salt, thiourea, and ammonia to form another n-type ZnS layer on the substrate before or after forming the ZnS layer.
